(19) United States
(12) Patent Application Publication
(10) Pub. No.: US 2025/0234668 A1
(43) Pub. Date: Jul. 17, 2025

(54) PHOTOELECTRIC PACKAGING STRUCTURE, PREPARATION METHOD AND CAMERA MODULE

(71) Applicant: TRIPLE WIN TECHNOLOGY (SHENZHEN) CO. LTD., New Taipei (CN)

(72) Inventors: HSIN-YEN HSU, New Taipei (TW); TZU-LI FENG, New Taipei (TW)

(21) Appl. No.: 19/014,506

(22) Filed: Jan. 9, 2025

(30) Foreign Application Priority Data
Jan. 16, 2024 (CN) 202410063768.7

(51) Int. Cl. H10F 39/00; H10F 71/00

(52) U.S. Cl. CPC H10F 39/811; H10F 39/024; H10F 39/804; H10F 39/8063; H10F 71/136

(57) ABSTRACT

A photoelectric packaging structure, and a preparation method of the photoelectric packaging structure, and a camera module having the photoelectric packaging structure are provided. The photoelectric packaging structure includes a substrate module and a photosensitive chip. The substrate module includes a substrate, and the substrate module defines a plurality of channels. The photosensitive chip is located on the substrate, and includes a photosensitive area and a non-photosensitive area connected to the photosensitive area. Two ends of each of the channels extend to the substrate and the non-photosensitive area, respectively. A conductive layer is formed on an inner wall of each of the channels to form a hollow conductive channel. The hollow conductive channel is electrically connected to the substrate and the non-photosensitive area.

### FIELD

The subject matter herein generally relates to semiconductor packages, and more particularly, to a photoelectric packaging structure, and a preparation method of the photoelectric packaging structure, and a camera module having the photoelectric packaging structure.

### BACKGROUND

Camera modules may include substrates and photosensitive chips mounted on the substrates. The substrate may electrically connect to the photosensitive chip through a wire bonding packaging technology or flip chip packaging technology, thereby enabling the signal transmission between the substrate and the photosensitive chip.

However, in the wire bonding packaging, since a certain space may be required for operating a wire bonding tool, a connection path between the substrate and the photosensitive chip may be long, which is not conducive to the miniaturization of the packaging structure. The flip chip packaging technology requires the substrate to have a high flatness and symmetrically distributed solder joints, such that the flip chip packaging technology has a low universality. Improvements in the art are desired.

### BRIEF DESCRIPTION OF THE DRAWINGS

FIG. 1 is a diagrammatic view of a camera module according to an embodiment of the present disclosure.

FIG. 2 is a diagrammatic view of a photoelectric packaging structure of the camera module shown in FIG. 1.

FIG. 3 is a diagrammatic view of the photoelectric packaging structure according to another embodiment.

FIG. 4 is a diagrammatic view of the photoelectric packaging structure according to yet another embodiment.

FIG. 5 is a diagrammatic view of the photoelectric packaging structure according to yet another embodiment.

FIG. 6 is a top view of a board according to an embodiment of the present disclosure.

FIG. 7 is a diagrammatic view showing a second plastic encapsulation block

formed on a photosensitive chip according to an embodiment of the present disclosure.

FIG. 8 is a diagrammatic view showing the board of FIG. 6 stacked on the structure of FIG. 7 to obtain an intermediate body.

FIG. 9 is a diagrammatic view showing the intermediate body of FIG. 8 pressed together.

FIG. 10 is a diagrammatic view showing channels defined in the plastic encapsulation body of FIG. 9.

FIG. 11 is a diagrammatic view showing a conductive layer formed in the channel of FIG. 10.

FIG. 12 is a diagrammatic view of a photoelectric packaging structure according to another embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Implementations of the present disclosure will now be described, by way of embodiments, with reference to the above figures. The embodiments are obviously a portion but not all of the embodiments of the present disclosure.

When a component is fixed to another component, the two components may be directly fixed to each other or indirectly fixed to each other or through an intermediate medium. When a component is located on another component, the component may be directly located on the another component, or an intermediate medium may exist therebetween.

Unless otherwise defined, the technical terms used in the present disclosure have the same meanings as those commonly understood by those skilled in the art. The terms used in the present disclosure are for describing specific embodiments but not intended to limit the scope of present disclosure.

In an existing photoelectric packaging structure, the substrate may electrically connect to the photosensitive chip through a wire bonding packaging technology or flip chip packaging technology, thereby enabling the signal transmission between the substrate and the photosensitive chip.

In the wire bonding packaging technology, metal wires are used to connect the substrate to the photosensitive chip, thereby achieving the electrical connection between the photosensitive chip and the substrate. However, the wire bonding packaging technology requires an operation space for the wire bonding tool, resulting in a large lateral distance from the photosensitive chip to the substrate, which is not conducive to the miniaturization of the packaging structure. Also, the metal wires are thin and brittle, such that other components cannot be installed inside the space occupied by the metal wires.

In the flip chip packaging technology, metal balls or metal posts are used to connect the substrate to the photosensitive chip, thereby achieving the electrical connection between the substrate and the photosensitive chip. In the flip chip packaging process, due to the size limitation of the metal balls, a high flatness of the substrate is required. Furthermore, when the photosensitive chip is soldered to the substrate, to allow all solder points of the chip to be simultaneously soldered to the substrate, the solder points need to be symmetrically distributed. As such, when pressure or ultrasonic energy is applied onto the photosensitive chip, the energy may be uniformly transferred to the chip. Thus, the flip chip packaging technology has a low universality.

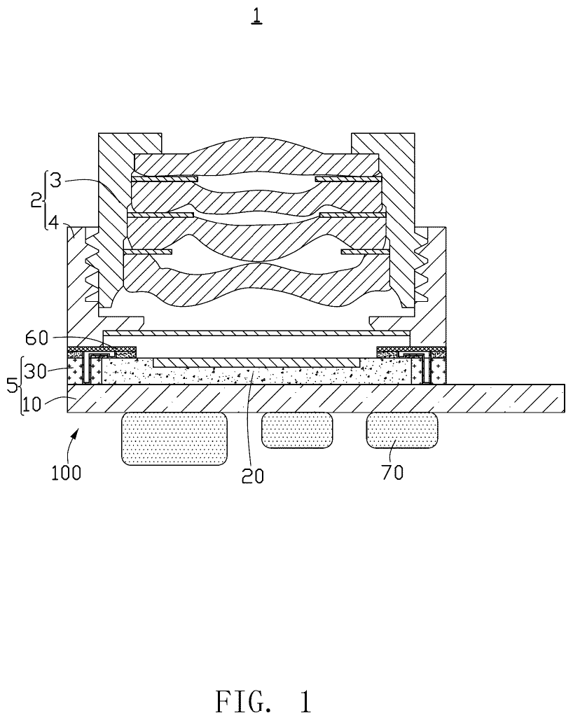

Referring to FIG. 1, a camera module 1 is provided according to an embodiment of the present disclosure. The camera module 1 includes a lens assembly 2 and a photoelectric packaging structure 100. The lens assembly 2 defines a photosensitive path for light signals of an ambient environment to pass through. The photoelectric packaging structure 100 receives the light signals of the ambient environment passing through the lens assembly 2, and convert the light signals into corresponding electrical signals. Thus, photoelectric conversion is achieved by the photoelectric packaging structure 100.

The lens assembly 2 includes at least one lens 3 and a lens holder 4. The lens holder 4 is mounted on the photoelectric packaging structure 100. The at least one lens 3 is mounted in the lens holder 4. The light signals of the ambient environment enter the camera module 1 through the at least one lens 3.

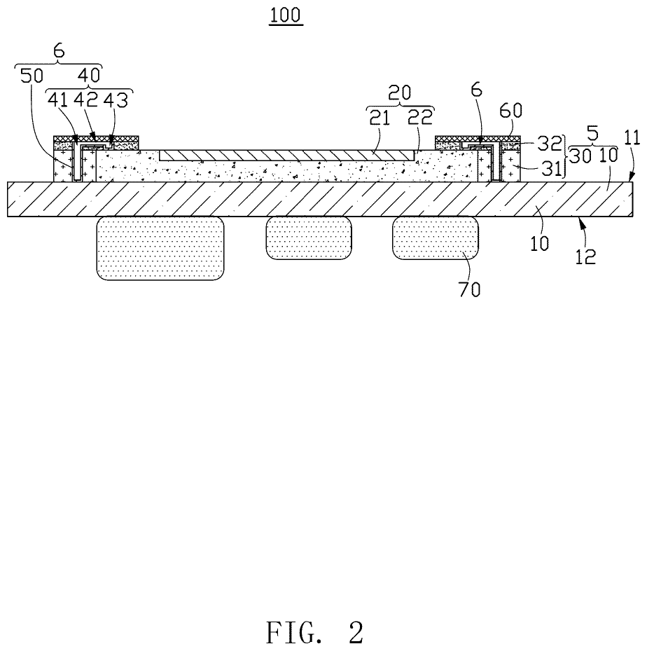

Referring to FIGS. 1 and 2, the photoelectric packaging structure 100 includes a substrate module 5 and a photosensitive chip 20. The substrate module 5 includes a substrate 10 and a plastic encapsulation body 30. The plastic encapsulation body 30 is located on the substrate 10. The lens holder 4 is located on the substrate 10 or the plastic encapsulation body 30. When the lens holder 4 is located on the plastic encapsulation body 30, the lateral size of the camera module 1 may be reduced, which is conducive to the miniaturization of the camera module 1. When the lens holder 4 is located on the substrate 10 (not shown), the substrate 10 is received the lens holder 4. The embodiment takes the lens holder 4 being located on the plastic encapsulation body 30 as an example, and the photosensitive chip 20 is packaged by the plastic encapsulation body 30.

Referring to FIGS. 1 and 2, the substrate 10 includes a first surface 11 and a second surface 12 opposite to each other. The photosensitive chip 20 is located on the first surface 11 or the second surface 12 of the substrate 10. The photosensitive chip 20 includes a photosensitive area 21 and a non-photosensitive area 22 connected to the photosensitive area 21. The non-photosensitive area 22 may surround the photosensitive area 21. The photosensitive area 21 receives the light signals of the ambient environment passing through the lens 3, and converts the light signals into the electrical signals.

Referring to FIG. 2, there are a number of channels 40 defined in the substrate module 5. Two ends of each of the channels 40 extend to the substrate 10 and the non-photosensitive area 22. respectively. A conductive layer 50 is formed on the inner wall of the channel 40, thereby obtaining a hollow conductive channel 6. The hollow conductive channel 6 is electrically connected to substrate 10 and non-photosensitive area 22. Two ends of the conductive layer 50 extend toward the substrate 10 and the non-photosensitive area 22.

In the present disclosure, the two ends of the channel 40 extend toward the electrical connection portions (such as solder pads) of the substrate 10 and the photosensitive chip 20. The two ends of the hollow conductive channel 6 are electrically connected to the electrical connection portions of the substrate 10 and the photosensitive chip 20. That is, the two ends of the conductive layer 50 are electrically connected to the electrical connection portions of the substrate 10 and the photosensitive chip 20. As such, the substrate 10 is electrically connected to the non-photosensitive area 22 of the photosensitive chip 20. Thus, the existing metal wires are not needed in the present disclosure. Moreover, the shape of the channel 40 may be varied in the present disclosure according to needs, thereby adjusting the shape of the hollow conductive channels 6. Thus, the lateral path between the substrate 10 and the non-photosensitive area 22 may be shortened without the limitation by the wire bonding tools. Moreover, since the shape of the channel 40 may also be changed according to the installation position of other components, the thickness of the photoelectric packaging structure 100 may also be reduced to a certain extent. Since the metal wires are not needed in the present disclosure, the installation positions of other components will not be limited around the metal wires due to the brittleness of the metal wires, thereby facilitating the miniaturization of the photoelectric packaging structure 100.

Meanwhile, compared to the flip chip packaging technology, the present disclosure forms the conductive layer 50 on the inner wall of the channel 40 to obtain the hollow conductive channel 6. Therefore, the package of the substrate 10 and the photosensitive chip 20 will not be limited by the size of the solder balls or by using symmetrically distributed solder joints. Thus, a high and strict flatness of the substrate 10 will not be need in the present disclosure.

In some embodiments, the plastic encapsulation body 30 and the photosensitive chip 20 are located on the same surface of the substrate 10, and the plastic encapsulation body 30 is at least adhered to the sidewall of the photosensitive chip 20. The plastic encapsulation body 30 improves the stability of the photosensitive chip 20. The channels are defined in the substrate 10 or the plastic encapsulation body 30. At least a portion of each of the channels 40 extends along a thickness direction of the photoelectric packaging structure 100, which facilitates the drilling of the channel 40 and the forming of the conductive layer 50 inside the channel 40. In some embodiments, a conductive ink is sprayed onto the inner wall of the channel 40, and the conductive ink is solidified to form the conductive layer 50.

The photoelectric packaging structure 100 will further be described as follows, when the photosensitive chip 20 is located on the first surface 11 and the second surface 12, respectively.

### First Embodiment

Referring to FIG. 2, in the embodiment, the photosensitive chip 20 is located on the first surface 11. The plastic encapsulation body 30 is at least adhered to the sidewall of the photosensitive chip 20. The channel 40 is located in plastic encapsulation body 30. The inner wall of channel 40 is provided with the conductive layer 50 to form the hollow conductive channel 6. The hollow conductive channel 6 is electrically connected to substrate 10 and non-photosensitive area 22. For example, the conductive layer 50 in the hollow conductive channel 6 is electrically connected to the solder pads (not shown) of the substrate 10 and the non-photosensitive area 22.

In some embodiments, the channel 40 includes a first channel portion 41, a second channel portion 42, and a third channel portion 43. The second channel portion 42 is connected between the first channel portion 41 and the third channel portion 43. Each of the first channel portion 41 and the third channel portion 43 extends in the plastic encapsulation body 30 along the thickness direction of the photosensitive chip 20. One end of the first channel portion 41 is connected to the substrate 10, and one end of the third channel portion 43 is connected to the non-photosensitive area 22. The plastic encapsulation body 30 functions as a carrier of the conductive layer 50, and the shape and position of the channel 40 in the plastic encapsulation body 30 may be varied according to actual needs.

Referring to FIG. 2, in some embodiments, each of the first channel portion 41 and the third channel portion 43 is in the shape of a through hole. The second channel portion 42 extends inside or on the surface of the plastic encapsulation body 30 along a horizontal direction perpendicular to the above thickness direction. An end of the first channel portion 41 is sealed by the substrate 10, and the solder pad (not shown) of the substrate 10 is exposed from the first channel portion 41, thereby allowing the conductive layer 50 of the first channel portion 41 to be electrically connected to the solder pad. Similarly, an end of the third channel portion 43 is sealed by the non-photosensitive area 22, and the solder pad (not shown) of the non-photosensitive area 22 is exposed from the third channel portion 43, thereby allowing the conductive layer 50 in the third channel portion 43 to be electrically connected to the solder pad. In the embodiment, the solder pad of the non-photosensitive area 22 is located on the surface of the photosensitive chip 20 away from the substrate 10.

Referring to FIG. 2, in some embodiments, the plastic encapsulation body 30 includes a first plastic encapsulation block 31 and a second plastic encapsulation block 32 located on the first plastic encapsulation block 31. The first plastic encapsulation block 31 is adhered to the sidewall of the photosensitive chip 20, and the second plastic encapsulation block 32 covers the first plastic encapsulation block 31 and at least a portion of the non-photosensitive area 22. The first channel portion 41 extends through the first plastic encapsulation block 31 and the second plastic encapsulation block 32. The third channel portion 43 extends through the second plastic encapsulation block 32. The second channel portion 42 is located in and exposed from the second plastic encapsulation block 32. The first plastic encapsulation block 31 and the second plastic encapsulation block 32 are glued together. In some embodiments, the second channel portion 42 is located on the top surface of the second plastic encapsulation block 32 or recessed from the top surface of the second plastic encapsulation block 32. When the second channel portion 42 is located on the surface of the second plastic encapsulation block 32 (not shown), a portion of the conductive layer 50 is laid flat on the second plastic encapsulation block 32. When the second channel portion 42 is a groove structure recessed from the top surface of the second plastic encapsulation block 32, the opening of the groove faces away from the first plastic encapsulation block 31 (see FIG. 2). When the second channel portion 42 is a groove structure, it facilitates the subsequent spraying of the conductive ink onto the inner wall of the second channel portion 42, and the conductive ink is then solidified to form the conductive layer 50. The groove structure also facilitates the spraying of the conductive ink onto the inner wall of the entire channel 40 along the horizontal direction.

The second plastic encapsulation block 32 functions as a carrier of the second channel portion 42 and the third channel portion 43. Since the plastic encapsulation body 30 includes the first plastic encapsulation block 31 and the second plastic encapsulation block 32, during the packaging process, the second encapsulation block 32 may first cover the non-photosensitive area 22, and then the first encapsulation block 31 is adhered to the sidewall of the photosensitive chip 20, which facilitates the assembly of the plastic encapsulation body 30 and also improves the yield of the photoelectric packaging structure 100. In other embodiments, the plastic encapsulation body 30 may also be integrally formed by injection molding on the photosensitive chip 20.

In some embodiments, to avoid short circuits caused by electrical connection of the conductive layer 50 exposed from the second plastic encapsulation block 32 to other functional components, a protective film 60 is further provided on the second plastic encapsulation block 32. The protective film 60 covers the second channel portion 42. In some embodiments, the protective film 60 is laid over the entire surface of the second plastic encapsulation block 32. The protective film 60 may include an ultraviolet adhesive.

The photoelectric packaging structure 100 according to the above embodiment has a flat surface, which facilitates the installation of the lens assembly 2 on the surface of the photoelectric packaging structure 100. A difference between the total length of the photoelectric packaging structure 100 and the length of the photosensitive chip 20 may be less than 500 μm, and a difference between the total width of the photoelectric packaging structure 100 and the width of the photosensitive chip 20 may be less than 500 μm. At the same time, the surface area of the photoelectric packaging structure 100 is smaller than that of the packaging structures prepared by the wire bonding packaging technology and the flip chip packaging technology, and the thickness of the photoelectric packaging structure 100 is also smaller than that of the packaging structure prepared by the flip chip packaging technology.

In some embodiments, the conductive layer 50 includes a conductive ink. The conductive ink may be free of particles. The conductive ink may also include at least one element from silver, platinum, gold, copper, nickel, and aluminum.

In some embodiments, the photoelectric packaging structure 100 further includes an electronic component 70. The electrical component 70 may be a passive component or an active component. The passive component includes a resistor or a capacitor. The active component includes a transistor, an integrated circuit, or a picture tube.

Referring to FIG. 2, in some embodiments, the electronic component 70 is located on the second surface 12 of the substrate 10.

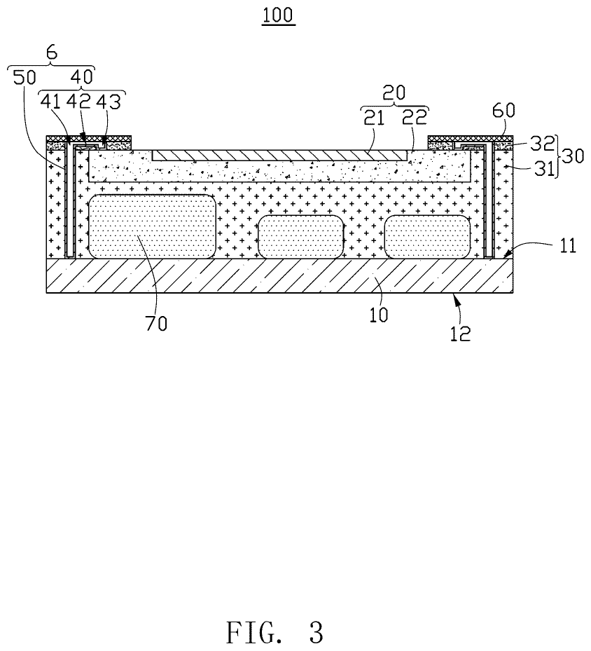

Referring to FIG. 3, in other embodiments, the electronic component 70 is located on the first surface 11 of the substrate 10 and embedded in the plastic encapsulation body 30. The electronic component 70 is sealed between the photosensitive chip 20 and the substrate 10. The first plastic encapsulation block 31 is located between the photosensitive chip 20 and the substrate 10, and extends out of the photosensitive chip 20 to wrap around the sidewall of the photosensitive chip 20, thereby improving the stability of the photosensitive chip 20 and the electronic component 70.

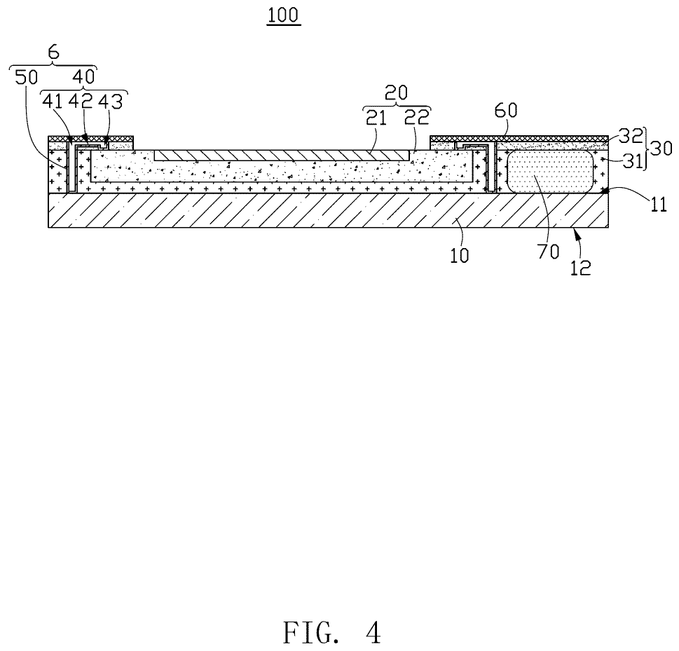

Referring to FIG. 4, in other embodiments, the electronic component 70 is located on one side of the photosensitive chip 20 and embedded in the first plastic encapsulation block 31.

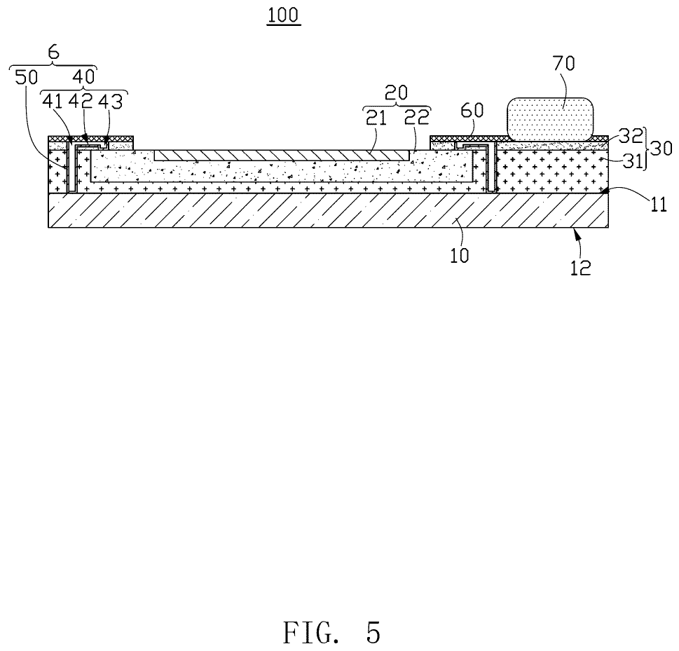

Referring to FIG. 5, in other embodiments, the electronic component 70 is located on one side of the photosensitive chip 20 and on the plastic encapsulation body 30, and the electronic component 70 is not embedded in the plastic encapsulation body 30

In some embodiments, the thickness of the conductive layer 50 is greater than or equal to 500 nm. The conductive ink is sprayed onto the inner wall of the channel 40 and solidified to obtain the desired thickness. In some embodiments, the thickness of the conductive layer 50 may also be varied according to actual needs, such that the impedance of the conductive layer 50 may be adjusted.

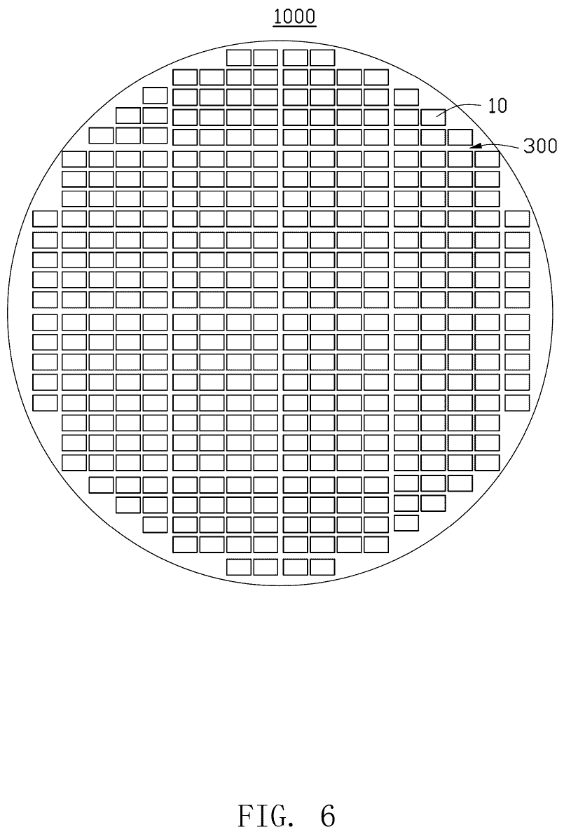

FIGS. 6 to 11 illustrate a preparation method of the photoelectric packaging structure 100 in accordance with an embodiment. The method is provided by way of embodiments, as there are a variety of ways to carry out the method. The method can begin at step S1.

Step S1, referring to FIG. 6, a board 1000 is provided, which includes multiple substrates 10 arranged in arrays. Two adjacent substrates 10 form a cutting area 300 therebetween.

Step S2, referring to FIG. 6, each substrate 10 is fabricated into a packaging unit 200. The fabrication of the package unit 200 may be carried out by the following steps.

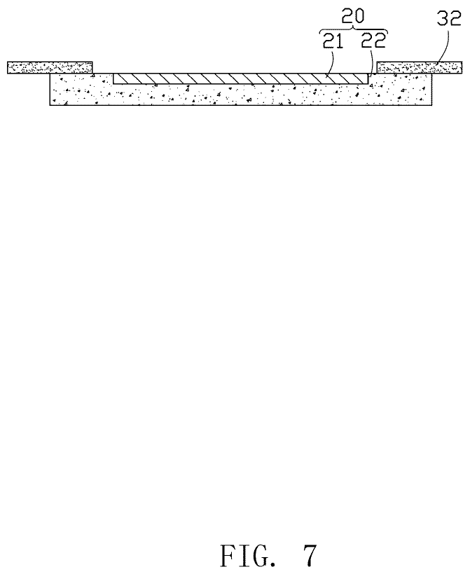

(1) Referring to FIG. 7, a photosensitive chip 20 and a second plastic encapsulation block 32 are provided. The photosensitive chip 20 includes a photosensitive area 21 and a non-photosensitive area 22 connected to the photosensitive area 21. The second plastic encapsulation block 32 is adhered to the non-photosensitive area 22 of the photosensitive chip 20.

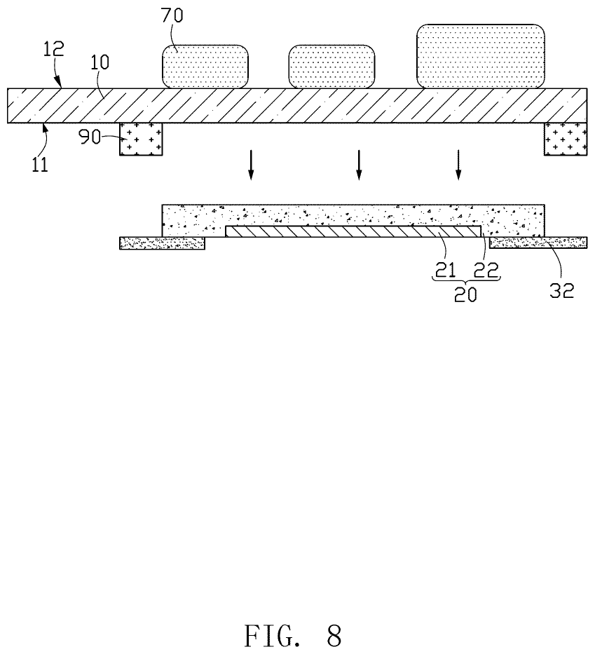

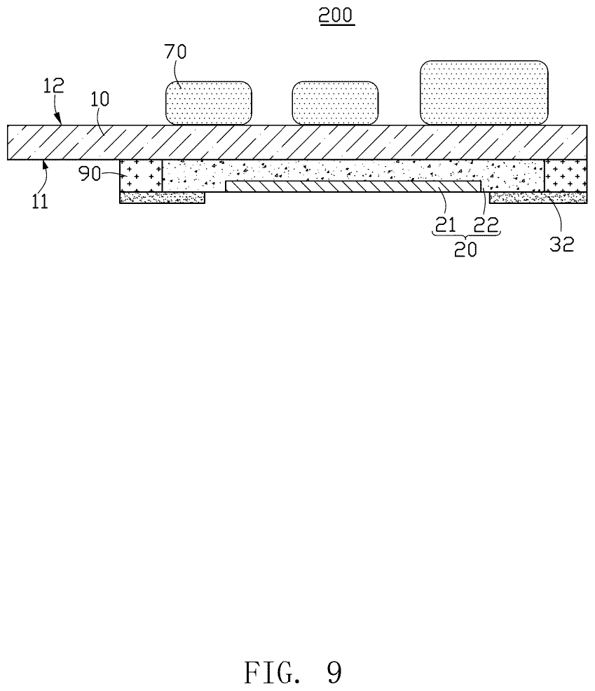

(2) Referring to FIGS. 8 and 9, the photosensitive chip 20 with the second plastic encapsulation block 32 is pressed and fixed onto one substrate 10. The substrate 10 further has a plastic encapsulation preform 90 thereon. The plastic encapsulation preform 90 is at least adhered to the sidewall of the photosensitive chip 20. The photosensitive chip 20 may be adhered to the substrate 10 through an insulating adhesive layer. The plastic encapsulation preform 90 may be formed on the substrate 10 by coating. After the pressing, the plastic encapsulation preform 90 is at least adhered to the sidewall of the photosensitive chip 20. The plastic encapsulation preform 90 is located between the second plastic encapsulation block 32 and the substrate 10.

In some embodiments, the electronic component 70 is adhered to the surface of the substrate 10 away from the photosensitive chip 20. The electronic component 70 may also embedded in the plastic encapsulation preform 90 and located between the photosensitive chip 20 and the substrate 10, at this time, the plastic encapsulation preform 90 is located between the photosensitive chip 20 and the substrate 10 and extends to the sidewall of the photosensitive chip 20. The electronic component 70 may also be embedded in the plastic encapsulation preform 90 and located on one side of the photosensitive chip 20. The electronic component 70 may also be located on one side of the photosensitive chip 20 and on the plastic encapsulation preform 90, and the electronic component 70 is not embedded in the plastic encapsulation preform 90. The position of the electrical component 70 may be set according to actual needs.

In some embodiments, the plastic encapsulation preform 31 is made of at least one of epoxy resin and phenolic resin. The second plastic encapsulation block 32 is made of at least one of polyimide adhesive, ultraviolet adhesive, black adhesive, and silicone.

(3) The plastic encapsulation preform 90 is solidified to obtain the first plastic encapsulation block 31. The first plastic encapsulation block 31 and the second plastic encapsulation block 32 constitute the plastic encapsulation body 30.

The plastic encapsulation preform 90 may be solidified by heating and pressure, thereby obtaining the first plastic encapsulation block 31 with stable structure and high strength in which photosensitive chip 20 is embedded. The first plastic encapsulation block 31 is located between the second plastic encapsulation block 32 and the substrate 10. After the plastic encapsulation preform 90 is heated and solidified, the first plastic encapsulation block 31 is adhered to the second plastic encapsulation block 32.

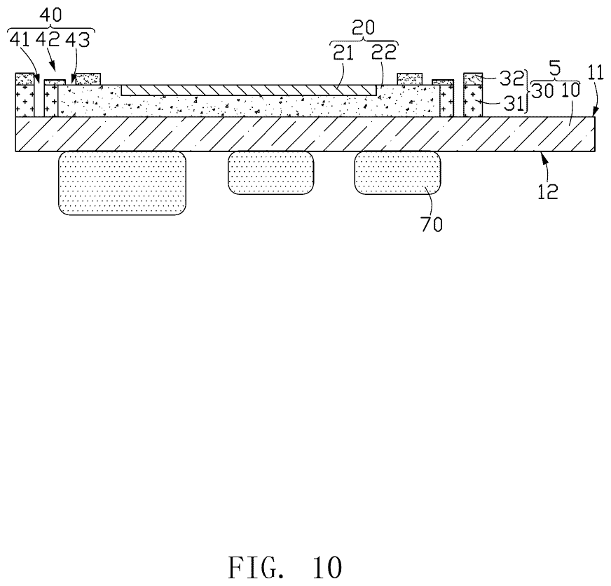

Step S3, referring to FIG. 10, a number of channels 40 are defined in the plastic encapsulation body 30 of the packaging unit 200, and the two ends of each of the channel 40 extend to the substrate 10 and the non-photosensitive area 22, respectively.

The channel 40 includes a first channel portion 41, a second channel portion 42, and a third channel portion 43. The second channel portion 42 is connected between the first channel portion 41 and the third channel portion 43. Each of the first channel portion 41 and the third channel portion 43 extends along the thickness direction of the photosensitive chip 20. One end of the first channel portion 41 is connected to the substrate 10, and one end of the third channel portion 43 is connected to the non-photosensitive area 22. The second channel portion 42 is exposed from the second plastic encapsulation block 32.

In some embodiments, the first channel portion 41 and the third channel portion 43 may be obtained by drilling, such as laser drilling, along the thickness direction of the package unit 200. In some embodiments, the second channel portion 42 is drilled on the second plastic encapsulation block 32 along a horizontal direction perpendicular to the thickness direction of the package unit 200, thereby obtaining a groove structure with an opening facing away from the substrate 10. In other embodiments, the second channel portion 42 is located on the top surface of the second plastic encapsulation block 32, and no drilling treatment is performed on the second plastic encapsulation block 32.

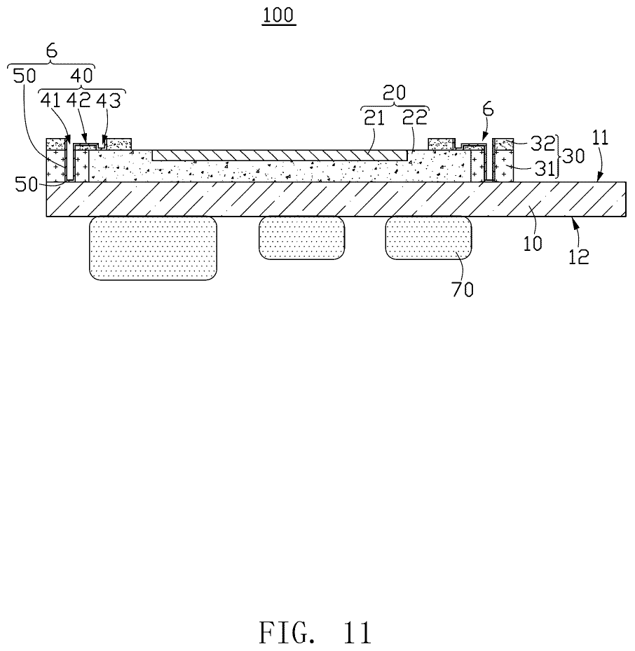

At S4, referring to FIG. 11, a conductive material is sprayed onto the inner wall of the channel 40. The conductive material is solidified to form a conductive layer 50 on the inner wall of channel 40, thereby obtaining a hollow conductive channel 6. The conductive layer 50 in the hollow conductive channel 6 is electrically connected to non-photosensitive area 22 and the substrate 10.

The conductive material may be sprayed onto the inner wall of the first channel portion 41, the second channel portion 42, and the third channel portion 43 of the channel 40 in sequence by a nozzle. The conductive material may include a conductive ink. When the conductive ink is used, and the inner diameter of the channel 40 may be less than 50 μm. If other conductive materials (such as conductive silver paste) are used, the inner diameter of channel 40 should be greater than 250 μm to enable the conductive silver paste to successively form inside the channel 40. Thus, by using the conductive ink in the present disclosure, the channel 40 may be formed with a small diameter, which is conducive to the miniaturization of the photoelectric packaging structure 100.

When the conductive material includes the conductive ink, the solidification of the conductive ink includes a first solidification stage and a second solidification stage after the first solidification stage.

The first solidification stage includes irradiating the conductive ink with ultraviolet light after the conductive ink is sprayed onto the inner wall of the channel 40, thereby pre-solidifying the conductive ink. At the first solidification stage, the ultraviolet irradiation is used to rapidly pre-solidify the conductive ink and prevent the flow of the conductive ink. The ultraviolet irradiation may be performed for a few seconds, such as for 1 second to 5 seconds.

The second solidification stage includes baking the pre-solidified conductive ink to obtain the conductive layer 50, thereby forming the hollow conductive channel 6. After the first solidification stage, the conductive ink is pre-formed on the inner wall of channel 40. The conductive ink is then baked at a temperature of 60° C. to 100° C. for a duration of 0.5 h to 3 h, thereby allowing the conductive ink to be completely solidified on the inner wall of the channel 40.

In other embodiments, the conductive layer 50 may also be formed on the inner wall of the channel 40 by electroplating.

At S5, referring to FIG. 2, a protective film 60 is coated on the surface of the second plastic encapsulation block 32 to obtain the photovoltaic packaging structure 100.

The protective film 60 blocks the second channel portion 42 and prevents short circuits caused by the conductive layer 50 in the second channel portion 42 being in contact with other components in the photoelectric packaging structure 100.

After the protective film 60 is formed on the packaging unit 200, the board 1000 is cut along the cutting area 300 to obtain a number of photoelectric packaging structures 100.

In the present disclosure, the hollow conductive channel 6 is formed by defining the channel 40 in the substrate module 5 and forming the conductive layer 50 in the channel 40. The hollow conductive channel 6 achieves the electrical connection between the substrate 10 and the non-photosensitive area 22. Thus, the existing metal wires are not needed in the present disclosure. Moreover, the shape of the channel 40 may be varied in the present disclosure according to needs, thereby adjusting the shape of the hollow conductive channels 6. Thus, the lateral path between the substrate 10 and the non-photosensitive area 22 may be shortened without the limitation by the wire bonding tools. Moreover, since the shape of the channel 40 may also be changed according to the installation position of other components, the thickness of the photoelectric packaging structure 100 may also be reduced to a certain extent. Since the metal wires are not needed in the present disclosure, the installation positions of other components will not be limited around the metal wires due to the brittleness of the metal wires, thereby facilitating the miniaturization of the photoelectric packaging structure 100.

### Second Embodiment

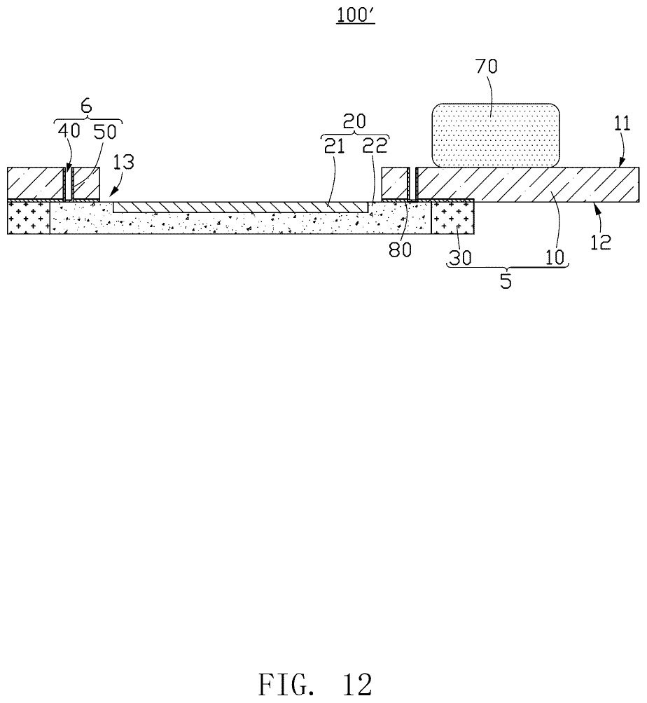

A photoelectric packaging structure 100′ is also provided according to another embodiment of the present disclosure. The difference between the photoelectric packaging structure 100′ and the photoelectric packaging structure 100 includes that the substrate 10 defines a slot 13 as shown in FIG. 12, and the photosensitive chip 20 is installed on the second surface 12 in a flipped manner. The photosensitive area 21 is exposed from the slot 13. The non-photosensitive area 22 is adhered to the second surface 12. The channel 40 is located in and extends through the substrate 10. One end of the channel 40 extends toward the non-photosensitive area 22. The conductive layer 50 is formed on the inner wall of the channel 40 to obtain the hollow conductive channel 6. The hollow conductive channel 6 is electrically connected to the substrate 10 and the non-photosensitive area 22.

In the embodiment, the channel 40 extends along the thickness direction of the photosensitive chip 20, and the pad of the non-photosensitive area 22 are exposed from the channel 40. The two ends of the conductive layer 50 in the hollow conductive channel 6 are electrically connected to the pads of the non-photosensitive area 22 and the substrate 10, respectively.

In the embodiment, the plastic encapsulation body 30 is made of a same material of the first plastic encapsulation block 31 in the first embodiment. The plastic encapsulation body 30 is formed on the sidewall of the photosensitive chip 20. There is also an adhesive layer 80 between the photosensitive chip 20 and the second surface 12. The plastic encapsulation body 30 is also adhered to the second surface 12 through the glue layer 80.

The difference between the preparation methods of the photoelectric packaging structure 100′ and the photoelectric packaging structure 100 includes that when preparing the package unit 200, step (1) for forming the second plastic encapsulation block 32 in the first embodiment is omitted, and the photosensitive chip 20 is located on the second surface 12 of the substrate 10.

Furthermore, at step S2, the channel 40 is located in the substrate 10. For example, the channel 40 is first defined in the substrate 10, the conductive material (such as conductive ink) is sprayed onto the inner wall of the channel 40, and the conductive material is solidified to form the conductive layer 50, thereby forming the hollow conductive channel 6. The hollow conductive channel 6 is electrically connected to the non-photosensitive area 22 and the substrate 10.

Even though information and advantages of the present embodiments have been set forth in the foregoing description, together with details of the structures and functions of the present embodiments, the disclosure is illustrative only. Changes may be made in detail, especially in matters of shape, size, and arrangement of parts within the principles of the present embodiments to the full extent indicated by the plain meaning of the terms in which the appended claims are expressed.

What is claimed is:

1. A photoelectric packaging structure comprising:
a substrate module comprising a substrate, and the substrate module defining a plurality of hollow conductive channels;
a photosensitive chip located on the substrate, and comprising a photosensitive area and a non-photosensitive area connected to the photosensitive area;
wherein each of the plurality of hollow conductive channels comprises a channel and a conductive layer formed on an inner wall of the channel, two ends of the channel extend to the substrate and the non-photosensitive area, respectively, and each of the plurality of hollow conductive channels is electrically connected to the substrate and the non-photosensitive area of the photosensitive chip.

2. The photoelectric packaging structure according to claim 1, wherein the substrate comprises a first surface and a second surface opposite to each other, the substrate module further comprises a plastic encapsulation body, the plastic encapsulation body and the photosensitive chip are located on one of the first surface and the second surface, the plastic encapsulation body is at least adhered to a sidewall of the photosensitive chip, and the channel is defined in the substrate or the plastic encapsulation body.

3. The photoelectric packaging structure according to claim 2, wherein the photosensitive chip is located on the first surface, the channel is defined in the plastic encapsulation body, the channel comprises a first channel portion, a second channel portion, and a third channel portion, the second channel portion is connected between the first channel portion and the third channel portion, each of the first channel portion and the third channel portion extends along a thickness direction of the photosensitive chip, one end of the first channel portion is connected to the substrate, and one end of the third channel portion is connected to the non-photosensitive area.

4. The photoelectric packaging structure according to claim 3, wherein the plastic encapsulation body comprises a first plastic encapsulation block and a second plastic encapsulation block formed on the first plastic encapsulation block, the first plastic encapsulation block is adhered to the sidewall of the photosensitive chip, the second plastic encapsulation block at least covers a portion of the non-photosensitive area, the first channel portion extends through the first plastic encapsulation block and the second plastic encapsulation block, the third channel portion extends through the second plastic encapsulation block, and the second channel portion is exposed from the second plastic encapsulation block.

5. The photoelectric packaging structure according to claim 4, further comprising a protective film, wherein the protective film is formed on the second plastic encapsulation block and covers the second channel portion.

6. The photoelectric packaging structure according to claim 1, wherein the conductive layer comprises a conductive material, and the conductive material comprises a conductive ink or a conductive silver paste.

7. The photoelectric packaging structure according to claim 2, wherein the substrate defines a slot, the photosensitive chip is located on the second surface, the photosensitive area is exposed from the slot, the non-photosensitive area is adhered to the second surface, the channel extends through the substrate, one end of the channel extends to the non-photosensitive area.

8. The photoelectric packaging structure according claim 2, wherein the photoelectric packaging structure further comprises an electrical component, wherein the electrical component is embedded in the plastic encapsulation body, or located on the plastic encapsulation body, or located on the substrate.

9. The photoelectric packaging structure according to claim 1, wherein a thickness of the conductive layer is greater than or equal to 500 nm.

10. A preparation method of a photoelectric packaging structure, comprising:
forming a photosensitive chip on a substrate of a substrate module;
defining a plurality of channels in the substrate module, wherein two ends of each of the plurality of channels extend to the substrate and a non-photosensitive area of the photosensitive chip, respectively;
forming a conductive layer on an inner wall of each of the plurality of channels to form a hollow conductive channel, wherein the hollow conductive channel is electrically connected to the substrate and the non-photosensitive area, thereby obtaining the photoelectric packaging structure.

11. The preparation method according to claim 10, wherein the substrate comprises a first surface and a second surface opposite to each other, the substrate module further comprises a plastic encapsulation body, the photosensitive chip and the plastic encapsulation body are located on a same surface of the substrate, and the plastic encapsulation body is at least attached to a sidewall of the photosensitive chip.

12. The preparation method according to claim 11, wherein the plurality of channels is located in the plastic encapsulation body, and forming the photosensitive chip on the substrate comprises:
forming a second plastic encapsulation block on the non-photosensitive area of the photosensitive chip;
installing the photosensitive chip with the second plastic encapsulation block on the substrate, wherein the substrate further comprises a plastic encapsulation preform thereon, and the plastic encapsulation preform is at least adhered to the sidewall of the photosensitive chip;
solidifying the plastic encapsulation preform to obtain a first plastic encapsulation block, wherein the first plastic encapsulation block and the second plastic encapsulation block constitute the plastic encapsulation body.

13. The preparation method according to claim 12, wherein when installing the photosensitive chip on the substrate, the plastic encapsulation preform is located between the photosensitive chip and the substrate, and extends to the sidewall of the photosensitive chip.

14. The preparation method according to claim 11, wherein the plurality of channels is defined in the substrate, and forming the photosensitive chip on the substrate comprises:
installing the photosensitive chip on the second surface, wherein the photosensitive chip further comprises a photosensitive area connected to the non-photosensitive area, the substrate further defines a slot, the photosensitive area is exposed from the slot, the non-photosensitive area is adhered to the second surface, a plastic encapsulation preform is further provided on the second surface, and the plastic encapsulation preform is at least adhered to the sidewall of the photosensitive chip; and
solidifying the plastic encapsulation preform to obtain the plastic encapsulation body.

15. The preparation method according to claim 10, wherein forming the conductive layer on the inner wall of each of the plurality of channels comprises:
installing a conductive material on the inner wall of each of the plurality of channels; and
solidify the conductive material to form the conductive layer.

16. The preparation method according to claim 15, wherein the conductive material comprises a conductive ink or a conductive silver paste.

17. The preparation method according to claim 16, wherein solidify the conductive material comprises a first solidification stage and a second solidification stage after the first solidification stage;
the first solidification stage comprises spraying the conductive ink onto the inner wall of each of the plurality of channels, and irradiating the conductive ink with ultraviolet light to pre-solidify the conductive ink; and
the second solidification stage comprises baking the pre-solidified conductive ink to obtain the conductive layer.

18. The preparation method according to claim 10, further comprising:
providing a board comprising a plurality of substrates arranged in arrays, wherein adjacent two of the plurality of substrates form a cutting area therebetween;
fabricating each of the plurality of substrates into a package unit, wherein the package unit comprises one of the plurality of substrates and the photosensitive chip located on the one of the plurality of substrates; and
forming the conductive layer in the package unit to form the hollow conductive channel, and cutting the board along the cutting area to obtain a plurality of photoelectric packaging structures.

19. A camera module comprising:
a lens assembly; and
a photoelectric packaging structure comprising:
a substrate module comprising a substrate, and the substrate module defining a plurality of hollow conductive channels;
a photosensitive chip located on the substrate, and comprising a photosensitive area and a non-photosensitive area connected to the photosensitive area;
wherein each of the plurality of hollow conductive channels comprises a channel and a conductive layer formed on an inner wall of the channel, two ends of the channel extend to the substrate and the non-photosensitive area, respectively, each of the plurality of hollow conductive channels is electrically connected to the substrate and the non-photosensitive area of the photosensitive chip, and the lens assembly is located on the substrate module.
